(19) United States
(12) Patent Application Publication
(10) Pub. No.: US 2024/0130098 A1
(43) Pub. Date: Apr. 18, 2024

(54) FEEDER INSERTION/REMOVAL DEVICE AND COMPONENT MOUNTING SYSTEM

(71) Applicant: YAMAHA HATSUDOKI KABUSHIKI KAISHA, Iwata-shi, Shizuoka (JP)

(72) Inventor: Yukinari AWANO, Shizuoka (JP)

(73) Assignee: YAMAHA HATSUDOKI KABUSHIKI KAISHA, Iwata-shi, Shizuoka (JP)

(21) Appl. No.: 18/546,398

(22) PCT Filed: Feb. 22, 2021
(86) PCT No.: PCT/JP2021/006540

§ 371 Date: Aug. 14, 2023

(51) Int. Cl. H05K 13/02; H05K 13/08

(52) U.S. Cl. CPC H05K 13/02; H05K 13/082

(57) ABSTRACT

A feeder insertion/removal device includes an insertion and removal movement mechanism, a detection unit, and an insertion and removal control unit. The insertion and removal movement mechanism moves the feeder along an insertion and removal direction with respect to the holder. The detection unit detects a load index value that is an index of a load applied to the feeder by movement of the feeder at the time of insertion and removal of the feeder into and from the holder by the insertion and removal movement mechanism. The insertion and removal control unit controls the movement of the feeder at the time of insertion and removal into and from the holder by inputting at a drive signal to the insertion and removal movement mechanism based on the load index value detected by the detection unit.

### CROSS-REFERENCE TO RELATED APPLICATION

This application claims benefit of priority to International Patent Application No. PCT/JP2021/006540, filed Feb. 22, 2021, the entire contents of which are incorporated herein by reference.

### BACKGROUND

### Technical Field

The present disclosure relates to a feeder insertion/removal device for inserting and removing a feeder into and from each of a plurality of holders in a component mounter that mounts a component on a board, and a component mounting system including the feeder insertion/removal device.

### Background Art

A component mounter, which produces a component mounting board in which electronic components are mounted on a board such as a printed board, includes a plurality of holders that hold feeders that supply components in an insertable and removable manner, and a mounting head that mounts components supplied from the feeders held by the holders on the board. In this type of component mounter, after taking out the component supplied from the feeder, the mounting head repeatedly performs work of mounting the component on the board until all the components to be mounted are mounted on the board.

When it is difficult to accurately supply a component from the feeder, there is a possibility that productivity of the component mounting board in the component mounter is decreased. JP 2017-224771 A and Japanese Patent No. 6620306 disclose a technique for detecting occurrence of a defect in a feeder at the time of supplying a component. In this technique, the occurrence of a defect in the feeder is detected based on a current value of a drive motor in a tape feeding mechanism that feeds a tape storing a component. When occurrence of a defect in the feeder is detected, processing for eliminating the defect is performed.

However, only focusing on occurrence of a defect in a feeder at the supply of a component cannot be regarded as sufficiently taking accurate component supply performance by the feeder into consideration.

When the feeder is inserted into or removed from each of a plurality of holders, a catch or the like that hinders insertion and removal of the feeder may occur. For example, in a case where the feeder takes an abnormal attitude of inclining, or in a case where a failure such as scratches, abrasion, or attached foreign matter occurs in the feeder and the holder, there is a possibility that the feeder is caught at the time of insertion and removal thereof. In this case, it may be difficult to accurately insert and remove the feeder into and from the holder. Therefore, it might be difficult to accurately supply a component from the feeder, resulting in decreasing productivity of the component mounting board in the component mounter.

### SUMMARY

Accordingly, the present disclosure provides a feeder insertion/removal device capable of accurately inserting and removing a feeder into and from a plurality of holders in a component mounter, and a component mounting system including the feeder insertion/removal device.

A feeder insertion/removal device according to one aspect of the present disclosure is a device for inserting and removing a feeder that supplies a component into and from each of a plurality of holders capable of holding the feeder in a component mounter that mounts the component on a board. The feeder insertion/removal device includes an insertion and removal movement mechanism configured to move the feeder along an insertion and removal direction with respect to the holder; a detection unit configured to detect a load index value that is an index of a load applied to the feeder by movement of the feeder at the time of insertion and removal of the feeder into and from the holder by the insertion and removal movement mechanism; and an insertion and removal control unit configured to control the movement of the feeder at the time of insertion and removal into and from the holder by inputting a drive signal to the insertion and removal movement mechanism based on the load index value detected by the detection unit.

A component mounting system according to another aspect of the present disclosure includes a component mounter that has a plurality of holders each capable of holding a feeder that supplies a component, and mounts a component supplied by the feeder on a board; and the above feeder insertion/removal device for inserting and removing the feeder into and from each of the plurality of holders.

Objects, features, and advantages of the present disclosure will become more apparent from the following detailed description and the accompanying drawings.

### BRIEF DESCRIPTION OF THE DRAWINGS

FIG. 1 is a block diagram illustrating a configuration of a component mounting system to which a feeder insertion/removal device according to an embodiment of the present disclosure is applied;

FIG. 2 is a cross-sectional view illustrating a configuration of a component mounter included in the component mounting system;

FIG. 3 is an enlarged perspective view illustrating the vicinity of a component supply unit in the component mounter;

FIG. 4 is a view of the component supply unit in the component mounter as viewed from an X-axis direction;

FIG. 5 is a side view of a feeder insertion/removal device included in the component mounting system;

FIG. 6 is a graph illustrating a relationship between a load index value detected by a detection unit of the feeder insertion/removal device and a feeder moving distance;

FIG. 7A is a view illustrating how the feeder is inserted and removed into and from the holder by the feeder insertion/removal device;

FIG. 7B is a view illustrating how the feeder is inserted and removed into and from the holder by the feeder insertion/removal device;

FIG. 8A is a flowchart showing operation of the feeder insertion/removal device; and

FIG. 8B is a flowchart showing the operation of the feeder insertion/removal device.

### DETAILED DESCRIPTION

In the following, a feeder insertion/removal device and a component mounting system according to an embodiment of the present disclosure will be described with reference to the drawings.

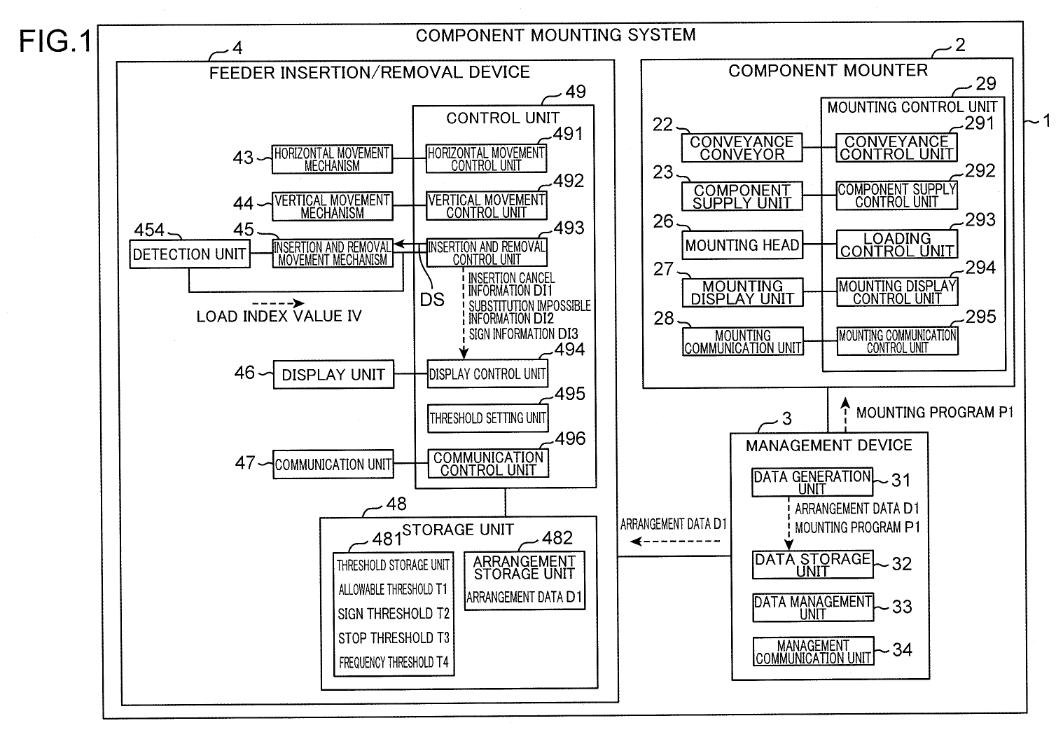

As illustrated in FIG. 1, a component mounting system 1 includes a component mounter 2, a management device 3, and a feeder insertion/removal device 4. In the component mounting system 1, the component mounter 2 and the management device 3 are data-communicably connected, and the management device 3 and the feeder insertion/removal device 4 are data-communicably connected.

The component mounting system 1 is a system that produces a component mounting board in which an electronic component (hereinafter, referred to as “component”) is mounted on a printed board (hereinafter, referred to as a “board”). In the component mounting system 1, the component mounter 2 produces a component mounting board, the production of the component mounting board by the component mounter 2 is managed by the management device 3, and the feeder insertion/removal device 4 executes pre-arrangement work necessary for the production of the component mounting board under the command of the management device 3.

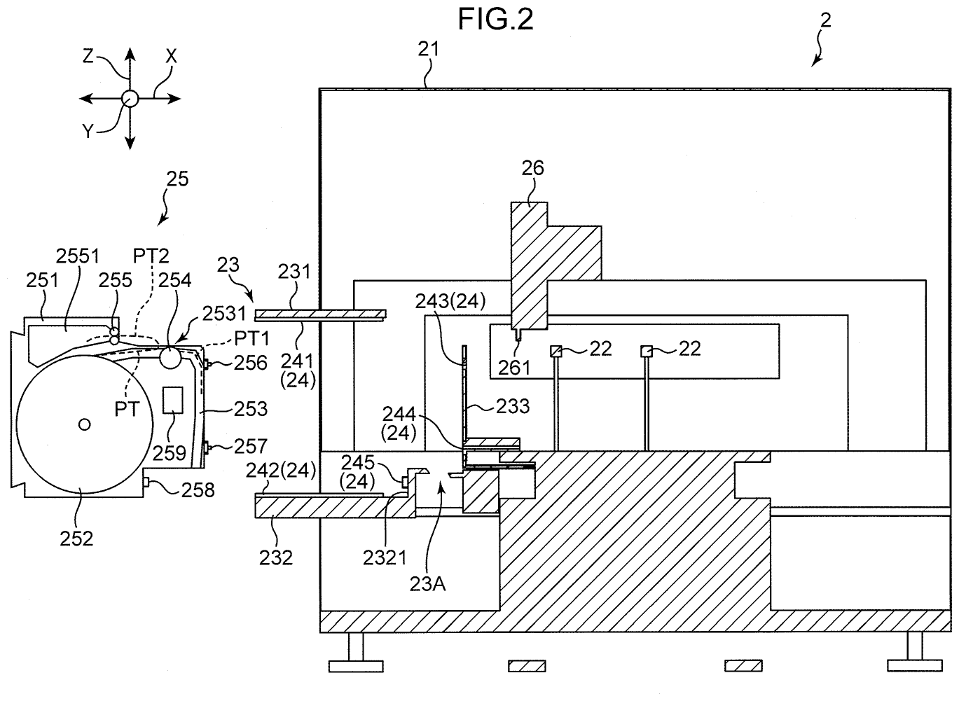

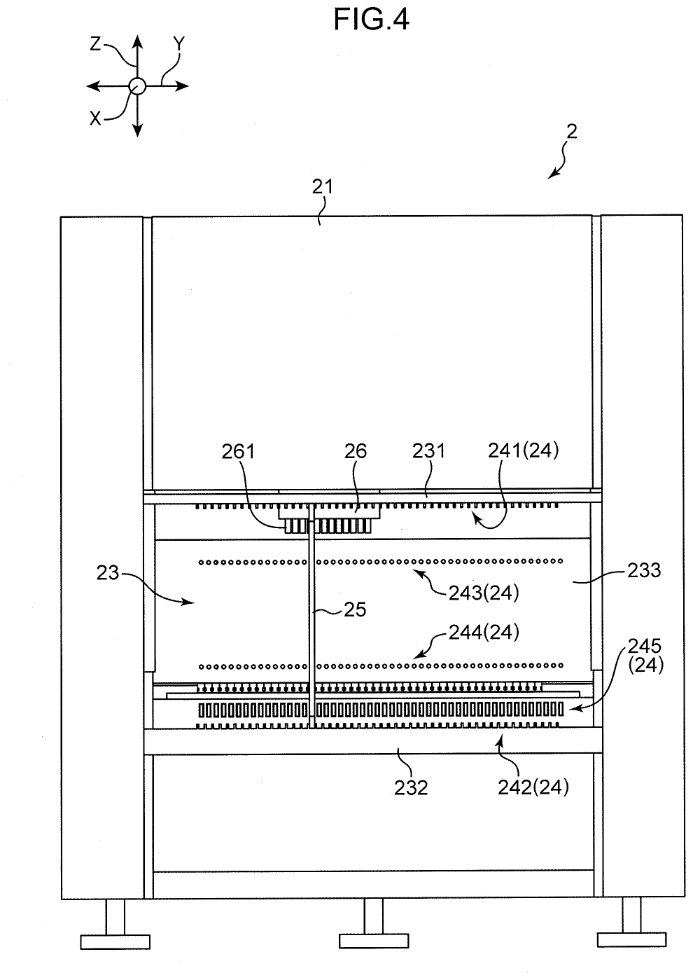

Description will be made of a configuration of the component mounter 2 with reference to FIGS. 2 to 4 in addition to FIG. 1. In the following, a directional relationship will be described using XYZ orthogonal coordinate axes. An X-axis direction and a Y-axis direction are orthogonal to each other on a horizontal plane, and a Z-axis direction is a direction extending in a vertical direction orthogonal to both the X-axis direction and the Y-axis direction.

The component mounter 2 is a device that mounts a component on a board to produce a component mounting board. Before components are mounted by the component mounter 2, a pattern of solder paste is printed on the board. In other words, the component mounter 2 mounts a component on a board on which a pattern of solder paste is printed by a pattern forming device. The component mounter 2 includes a mounter main body 21, a conveyance conveyor 22, a component supply unit 23, and a mounting head 26.

The mounter main body 21 is a housing structure having an internal space in which each part constituting the component mounter 2 is disposed. The conveyance conveyor 22 extends in the Y-axis direction and is disposed in a substantially central region inside the mounter main body 21. The conveyance conveyor 22 conveys the board in the Y-axis direction. The mounting head 26 mounts components on the board conveyed by the conveyance conveyor 22. The mounting head 26 takes out components from a feeder 25 disposed in the component supply unit 23, and mounts the taken out components on the board. A plurality of suction nozzles 261 are attached to the mounting head 26. The suction nozzle 261 is a holding tool capable of sucking and holding a component. The suction nozzle 261 is designed to be capable of communicating with any one of a negative pressure generation device, a positive pressure generation device, and the atmosphere via an electric switching valve. Specifically, supplying a negative pressure to the suction nozzle 261 enables the suction nozzle 261 to suck and hold a component (take out the component), and then supplying a positive pressure releases the suction holding of the component.

The component supply unit 23 is disposed in an end region of the mounter main body 21 in the X-axis direction. The component supply unit 23 includes an upper frame 231, a lower frame 232, and a back side frame 233 for forming a plurality of holders 24 that hold the feeder 25 that supplies components in an insertable and removable manner. The upper frame 231 is a plate-like frame spreading in the X-axis direction and the Y-axis direction. The upper frame 231 is disposed at one end in the X-axis direction of the mounter main body 21 so as to have a region on one end side in the X-axis direction exposed outward from the mounter main body 21 and have a region on the other end side in the X-axis direction accommodated in mounter main body 21. The lower frame 232 is a plate-like frame extending in the X-axis direction and the Y-axis direction, and is disposed on a lower side of the upper frame 231 in the Z-axis direction so as to be opposed to the upper frame 231. The lower frame 232 has a protrusion 2321 protruding upward in the Z-axis direction in the region on the other end side in the X-axis direction accommodated in the mounter main body 21. The back side frame 233 is a plate-like frame extending in the Y-axis direction and the Z-axis direction, and is disposed at a position closer to the center of the mounter main body 21 than the other ends of the upper frame 231 and the lower frame 232 in the X-axis direction inside the mounter main body 21.

Each of the plurality of holders 24 constitutes a part for holding the feeder 25 in an insertable and removable manner in the component supply unit 23. In the component supply unit 23, the plurality of holders 24 are arranged side by side in the Y-axis direction. The plurality of feeders 25 are disposed side by side in the Y axis direction by inserting the feeders 25 into the holders 24.

The feeder 25 is, for example, a tape feeder. The feeder 25 supplies components by feeding a component storage tape PT capable of storing a plurality of components. The component storage tape PT is configured with a carrier tape PT1 provided with a plurality of storage parts for storing components, and a cover tape PT2 joined to the carrier tape PT1 so as to cover the storage parts. The feeder 25 includes a feeder main body 251, a reel support part 252, a tape feeding part 254, and a collection part 255.

A tape feeding path 253 is formed in the feeder main body 251. The tape feeding path 253 is a channel through which the component storage tape PT is fed out, and has a component take-out part 2531 between an upstream end and a downstream end in a feeding direction of the component storage tape PT. The reel support part 252 is disposed on an upstream end side of the tape feeding path 253 in the feeder main body 251. The reel support part 252 supports a reel around which the component storage tape PT is wound.

The tape feeding part 254 is configured with, for example, a sprocket, and is disposed in the vicinity of the component take-out part 2531 of the tape feeding path 253. The tape feeding part 254 draws out the component storage tape PT from the reel supported by the reel support part 252, and feeds out the drawn out component storage tape PT along the tape feeding path 253. Operation of the tape feeding part 254 is controlled by a control circuit mounted on a control board 259. In the component storage tape PT fed out along the tape feeding path 253, the cover tape PT2 is peeled off from the carrier tape PT1 on the upstream side of the component take-out part 2531. As a result, the component is exposed on the carrier tape PT1 in the component take-out part 2531. The component exposed on the carrier tape PT1 can be taken out by the mounting head 26. In other words, the mounting head 26 takes out the component supplied by the feeder 25 from the component take-out part 2531.

The cover tape PT2 peeled off from the carrier tape PT1 on the upstream side of the component take-out part 2531 is collected by the collection part 255. The collection part 255 is configured with, for example, a pair of rollers in contact with each other. In this case, the collection part 255 collects the cover tape PT2 in accordance with rotation of the roller pair. The cover tape PT2 collected by the collection part 255 is accommodated in a collection box 2551.

The carrier tape PT1 from which the component has been taken out by the mounting head 26 is fed outward from the feeder 25 through a downstream end of the tape feeding path 253 by feeding operation of the tape feeding part 254. The carrier tape PT1 fed outward from the feeder 25 is cut to a predetermined length by a tape cutter 23A disposed in the vicinity of the protrusion 2321 of the lower frame 232 in the component supply unit 23.

In addition, as illustrated in FIG. 2, the feeder 25 has an upper positioning pin 256, a lower positioning pin 257, and a feeder side connector 258. The upper positioning pin 256 and the lower positioning pin 257 are pins provided so as to protrude from one end of the feeder main body 251 in the X axis direction. The upper positioning pin 256 and the lower positioning pin 257 are spaced apart from each other in the Z axis direction at the one end of the feeder main body 251 in the X axis direction, and the upper positioning pin 256 is positioned above the lower positioning pin 257. The one end of the feeder main body 251 in the X axis direction has a stepped portion recessed toward the other side in the X axis direction with respect to the part where the upper positioning pin 256 and the lower positioning pin 257 are provided. The feeder side connector 258 is provided at the stepped portion at the one end of the feeder main body 251 in the X axis direction. The feeder side connector 258 is a connector electrically connected to the control board 259.

The plurality of holders 24 for holding the feeders 25 in an insertable and removable manner are formed in the upper frame 231, the lower frame 232, and the back side frame 233 of the component supply unit 23. Each of the holders 24 includes an upper holding rail 241, a lower holding rail 242, an upper pin insertion hole 243, a lower pin insertion hole 244, and a unit side connector 245.

A plurality of the upper holding rails 241 are formed side by side in the Y axis direction so as to extend in the X axis direction on a lower surface of the upper frame 231. The upper holding rail 241 is a rail member that guides an upper end of the feeder 25 at the time of movement of the feeder 25 during insertion and removal into and from the holder 24. A plurality of the lower holding rails 242 are formed side by side in the Y axis direction so as to extend in the X axis direction on an upper surface of the lower frame 232. The lower holding rail 242 is a rail member that guides a lower end of the feeder 25 at the time of movement of the feeder 25 during insertion and removal into and from the holder 24.

The upper pin insertion holes 243 are a plurality of holes formed side by side in the Y-axis direction at an upper end of the back side frame 233. The upper pin insertion hole 243 allows insertion of the upper positioning pin 256 of the feeder 25 when the feeder 25 is inserted into the holder 24. On the other hand, when the feeder 25 is removed from the holder 24, the insertion of the upper positioning pin 256 into the upper pin insertion hole 243 is released. The lower pin insertion holes 244 are a plurality of holes formed side by side in the Y-axis direction at a lower end of the back side frame 233. The lower pin insertion hole 244 allows insertion of the lower positioning pin 257 of the feeder 25 when the feeder 25 is inserted into the holder 24. On the other hand, when the feeder 25 is removed from the holder 24, the insertion of the lower positioning pin 257 into the lower pin insertion hole 244 is released. The feeder 25 is positioned with respect to the holder 24 by inserting the upper positioning pin 256 into the upper pin insertion hole 243 and inserting the lower positioning pin 257 into the lower pin insertion hole 244.

A plurality of the unit side connectors 245 are provided side by side in the Y-axis direction on the protrusion 2321 of the lower frame 232, and are electrically connected to a mounting control unit 29 of the component mounter 2. The unit side connector 245 is connected to the feeder side connector 258 of the feeder 25 when the feeder 25 is inserted into the holder 24.

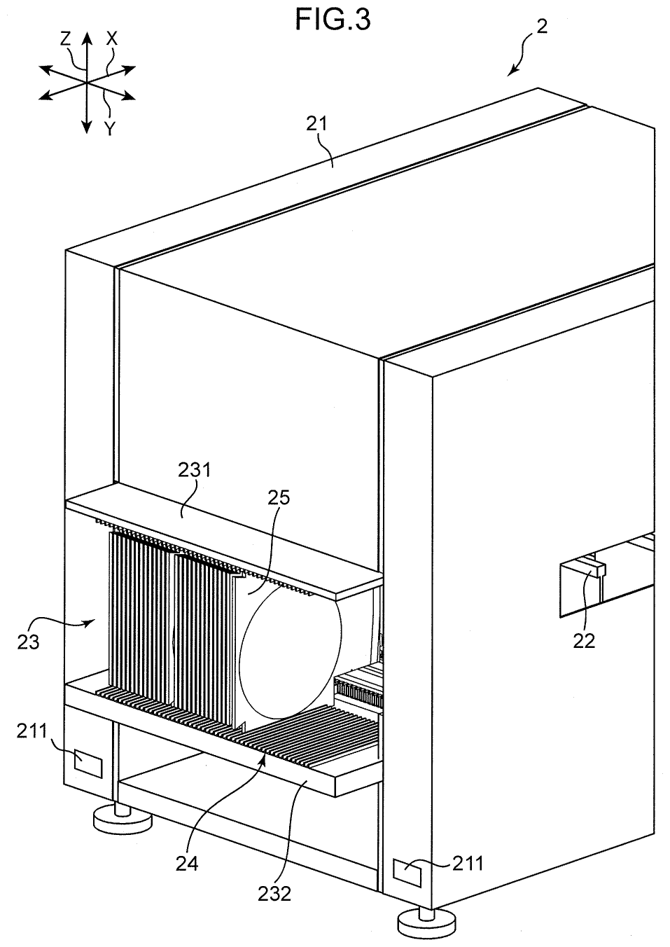

As illustrated in FIG. 3, a marking part 211 is provided in the vicinity of the component supply unit 23 in the mounter main body 21. The marking part 211 serves as a mark indicating a position of each of the plurality of holders 24 in the component supply unit 23.

As illustrated in FIG. 1, the component mounter 2 further includes a mounting display unit 27, a mounting communication unit 28, and a mounting control unit 29. As will be described in detail later, when information output from the feeder insertion/removal device 4 is input via the management device 3, the mounting display unit 27 displays the information. By checking the information displayed on the mounting display unit 27, an operator can grasp a condition of insertion and removal of the feeder 25 into and from the holder 24 by the feeder insertion/removal device 4. The mounting communication unit 28 is an interface circuit that realizes data communication with the management device 3.

The mounting control unit 29 is configured with a central processing unit (CPU), a read only memory (ROM) that stores a control program, a random access memory (RAM) used as a work area of the CPU, and the like. The mounting control unit 29 controls the mounting display unit 27 and the mounting communication unit 28 by the CPU executing the control program stored in the ROM, and controls each operation of the conveyance conveyor 22, the feeder 25 held by the holder 24 of the component supply unit 23, and the mounting head 26. The mounting control unit 29 includes, as a functional configuration, a conveyance control unit 291, a component supply control unit 292, a loading control unit 293, a mounting display control unit 294, and a mounting communication control unit 295.

The conveyance control unit 291 controls board conveyance operation by the conveyance conveyor 22. The component supply control unit 292 controls component supply operation of each feeder 25 held by each of the plurality of holders 24. The loading control unit 293 controls mounting operation of a component onto a board by the mounting head 26. The mounting display control unit 294 controls display operation for various types of information by the mounting display unit 27. The mounting communication control unit 295 controls data communication with the management device 3 by the mounting communication unit 28.

Next, the management device 3 will be described with reference to FIG. 1. The management device 3 is a device that manages production of a component mounting board by the component mounter 2 and transmits data necessary for the pre-arrangement work of inserting and removing the feeder 25 into and from each of the plurality of holders 24 to the feeder insertion/removal device 4. The management device 3 is configured with, for example, a microcomputer. The management device 3 includes a data generation unit 31, a data storage unit 32, a data management unit 33, and a management communication unit 34 as a functional configuration.

The data generation unit 31 generates arrangement data D1 indicating an arrangement position of the feeder 25 with respect to each holder 24 in the component supply unit 23 necessary for the production of the component mounting board by the component mounter 2. The arrangement data D1 is, for example, data indicating positions of the holders 24 in which the feeders 25 necessary for producing the component mounting board are arranged in a densely packed state so that a moving distance of the mounting head 26 becomes as short as possible when the component is mounted on the board. In addition, the data generation unit 31 generates a mounting program P1 indicating a procedure for mounting, on the board, a component supplied by the feeder 25 arranged in the holder 24 according to the arrangement data D1. In the mounting program P1, there is recorded information such as a mounting position of each component on the board, an arrangement position of the feeder 25 on the holder 24 according to the arrangement data D1, and a mounting order of components by the mounting head 26.

The arrangement data D1 and the mounting program P1 generated by the data generation unit 31 are stored in the data storage unit 32.

The data management unit 33 reads the arrangement data D1 and the mounting program P1 from the data storage unit 32 and distributes the same. Specifically, the data management unit 33 causes the arrangement data D1 to be transmitted to the feeder insertion/removal device 4 via the management communication unit 34, and causes the mounting program P1 to be transmitted to the component mounter 2 via the management communication unit 34.

The management communication unit 34 is an interface circuit that realizes data communication with the component mounter 2 and the feeder insertion/removal device 4. The management communication unit 34 receives data on a production condition of the component mounting board by the component mounter 2. In addition, under the control of the data management unit 33, the management communication unit 34 transmits the arrangement data D1, out of the arrangement data D1 and the mounting program P1 generated by the data generation unit 31, to the feeder insertion/removal device 4, and transmits the mounting program P1 to the component mounter 2.

In the component mounter 2, when the mounting communication unit 28 receives the mounting program P1 transmitted from the management communication unit 34, the production of the component mounting board is started based on the mounting program P1. At this time, component mounting operation by the mounting head 26 is executed according to the mounting program P1. Specifically, when the board is conveyed by the conveyance conveyor 22, the mounting head 26 takes out the component from each feeder 25 held by each holder 24 in the component supply unit 23 according to the mounting program P1. Thereafter, operation of the mounting head 26 of moving over the board and sequentially mounting the components is repeated in the mounting order of the components indicated by the mounting program P1 until all the components are mounted on the board.

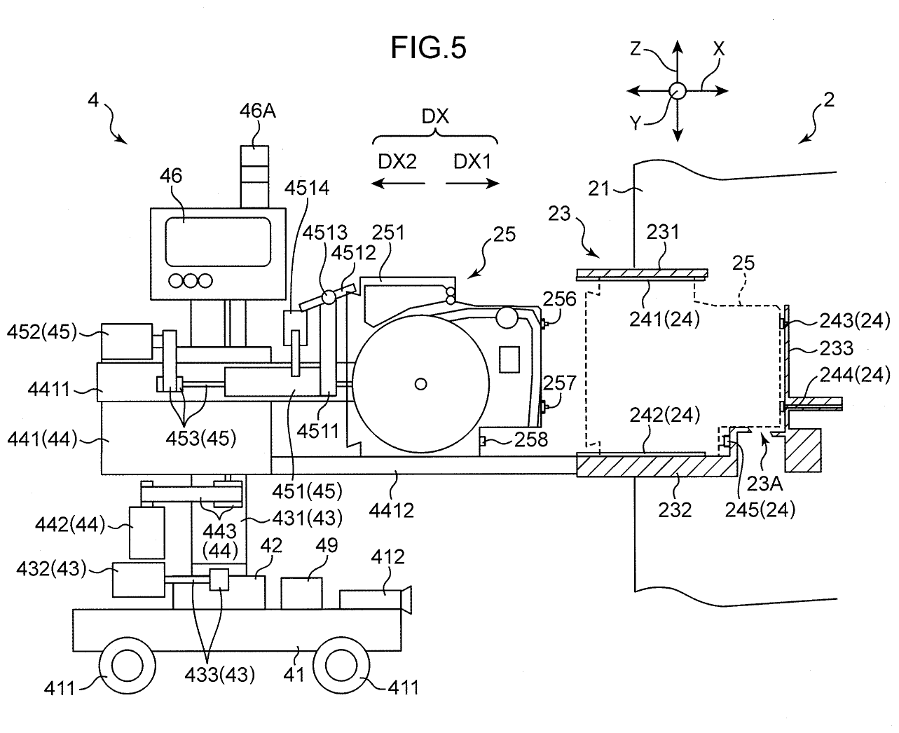

On the other hand, when receiving the arrangement data D1 transmitted from the management communication unit 34, the feeder insertion/removal device 4 performs the pre-arrangement work of inserting and removing the feeder 25 into and from each holder 24 in the component supply unit 23 based on the arrangement data D1. The feeder insertion/removal device 4 will be described with reference to FIGS. 5, 6, 7A, and 7B in addition to FIG. 1.

The feeder insertion/removal device 4 is a work robot that performs the pre-arrangement work of inserting and removing the feeder 25 into and from each of the plurality of holders 24. The feeder insertion/removal device 4 inserts and removes the feeder 25 into and from each of the holders 24 by moving the feeder 25 along an insertion and removal direction DX. The insertion and removal direction DX is a direction parallel to the X-axis direction in which the upper holding rail 241 and the lower holding rail 242 extend in each holder 24. An insertion direction DX1, which is a direction in which the feeder 25 is moved when the feeder 25 is inserted into each of the holders 24 and is one direction of the insertion and removal direction DX, is a direction from the outside to the inside of the mounter main body 21 along the X-axis direction. An extraction direction DX2, which is a direction in which the feeder 25 is moved when the feeder 25 is extracted from each of the holders 24, is a direction opposite to the insertion direction DX1.

The feeder insertion/removal device 4 moves the feeder 25 in the insertion direction DX1 based on the arrangement data D1 so that the feeder 25 necessary for the production of the component mounting board by the component mounter 2 is inserted into each holder 24. In addition, the feeder insertion/removal device 4 moves the feeder 25 in the extraction direction DX2 so that the feeder 25 that needs to be replaced due to a component shortage or the like is extracted from each holder 24. The feeder insertion/removal device 4 includes a base part 41, a horizontal support base 42, a horizontal movement mechanism 43, a vertical movement mechanism 44, an insertion and removal movement mechanism 45, a detection unit 454, a display unit 46, a communication unit 47, a storage unit 48, and a control unit 49.

Although details will be described later, the display unit 46 displays information (insertion cancel information DI1, substitution impossible information DI2, and sign information DI3) output from an insertion and removal control unit 493 of the control unit 49. By checking the information displayed on the display unit 46, the operator can grasp a condition of insertion and removal of the feeder 25 into and from the holder 24 by the feeder insertion/removal device 4. Note that a warning lamp 46A may be turned on in accordance with timing at which the display unit 46 displays various types of information.

The communication unit 47 is an interface circuit that realizes data communication with the management device 3. The communication unit 47 receives the arrangement data D1 transmitted from the management device 3. In addition, the communication unit 47 transmits information output from the insertion and removal control unit 493 to the management device 3. The information transmitted to the management device 3 via the communication unit 47 is input to the component mounter 2 and displayed on the mounting display unit 27.

The storage unit 48 includes a threshold storage unit 481 and an arrangement storage unit 482. The threshold storage unit 481 stores various preset thresholds (an allowable threshold T1, a sign threshold T2, a stop threshold T3, and a frequency threshold T4) for use when the insertion and removal control unit 493 controls the insertion and removal movement mechanism 45. The arrangement storage unit 482 stores the arrangement data D1 received by the communication unit 47.

The base part 41 is a base on which the horizontal movement mechanism 43 and the like are disposed in the feeder insertion/removal device 4. Wheels 411 are attached to the base part 41 so that the feeder insertion/removal device 4 can move, and a position detection sensor 412 is attached to the base part. The feeder insertion/removal device 4 moves to each position of the plurality of holders 24 in the component supply unit 23 by detecting, by the position detection sensor 412, the marking part 211 provided in the mounter main body 21.

The horizontal support base 42 is a base disposed on the base part 41. The horizontal support base 42 is a base extending horizontally along the Y-axis direction orthogonal to the insertion and removal direction DX on the horizontal plane. The horizontal support base 42 supports a horizontal movement strut body 431 of the horizontal movement mechanism 43 so as to be movable along the Y-axis direction.

The horizontal movement mechanism 43 is a mechanism configured to move the feeder 25 gripped by a grip part 4512 of an insertion and removal movable body 451 in the insertion and removal movement mechanism 45 in the Y-axis direction with respect to each holder 24. The horizontal movement mechanism 43 includes the horizontal movement strut body 431, a horizontal drive motor 432, and a horizontal drive transmission unit 433.

The horizontal movement strut body 431 is a strut extending in the Z-axis direction, and is supported by the horizontal support base 42 so as to be movable in the Y-axis direction. The horizontal movement strut body 431 supports a vertical movable body 441 of the vertical movement mechanism 44 so as to be movable along the Z-axis direction. The horizontal drive motor 432 is a drive motor that generates a driving force for moving the horizontal movement strut body 431 along the Y-axis direction on the horizontal support base 42. The horizontal drive transmission unit 433 is a mechanism for transmitting the driving force of the horizontal drive motor 432 to the horizontal movement strut body 431.

In the horizontal movement mechanism 43, the horizontal movement strut body 431 moves on the horizontal support base 42 in the Y-axis direction according to the driving force of the horizontal drive motor 432 transmitted from the horizontal drive transmission unit 433.

The vertical movement mechanism 44 is a mechanism configured to move the feeder 25 gripped by the grip part 4512 of the insertion and removal movable body 451 in the insertion and removal movement mechanism 45 in the Z-axis direction with respect to each holder 24. The vertical movement mechanism 44 includes the vertical movable body 441, a vertical drive motor 442, and a vertical drive transmission unit 443.

The vertical movable body 441 is supported by the horizontal movement strut body 431 so as to be movable in the Z-axis direction. The vertical movable body 441 has an insertion and removal support part 4411 extending along the insertion and removal direction DX (X-axis direction) and an insertion and removal guide part 4412 extending along the insertion and removal direction DX below the insertion and removal support part 4411. The insertion and removal support part 4411 supports the insertion and removal movable body 451 of the insertion and removal movement mechanism 45 so as to be movable along the insertion and removal direction DX. The insertion and removal guide part 4412 supports the feeder 25 gripped by the grip part 4512 of the insertion and removal movable body 451 from below, and guides movement of the feeder 25 along the insertion and removal direction DX accompanying the movement of the insertion and removal movable body 451. The vertical drive motor 442 is a drive motor that generates a driving force for moving the vertical movable body 441 in the Z-axis direction along the horizontal movement strut body 431. The vertical drive transmission unit 443 is a mechanism for transmitting the driving force of the vertical drive motor 442 to the vertical movable body 441.

In the vertical movement mechanism 44, the vertical movable body 441 moves along the horizontal movement strut body 431 in the Z-axis direction according to the driving force of the vertical drive motor 442 transmitted from the vertical drive transmission unit 443.

The insertion and removal movement mechanism 45 is a mechanism configured to move the feeder 25 along the insertion and removal direction DX with respect to each holder 24. The insertion and removal movement mechanism 45 includes the insertion and removal movable body 451, an insertion and removal drive motor 452, and an insertion and removal drive transmission unit 453.

The insertion and removal movable body 451 is supported by the insertion and removal support part 4411 of the vertical movable body 441 so as to be movable in the insertion and removal direction DX. The insertion and removal movable body 451 has a moving base body 4511 extending along the Z-axis direction, the grip part 4512 attached to an upper end of the moving base body 4511 so as to be rotatable around a rotation shaft 4513, and a cylinder 4514. The grip part 4512 grips an upper portion of the other end of the feeder main body 251 of the feeder 25 supported by the insertion and removal guide part 4412, the other end being opposite to one end in the X axis direction where the upper positioning pin 256 and the lower positioning pin 257 are provided. The cylinder 4514 moves in the Z-axis direction to rotate the grip part 4512 around the rotation shaft 4513. When the grip part 4512 rotates in accordance with the movement of the cylinder 4514, an attitude of the feeder 25 gripped by the grip part 4512 can be changed. The insertion and removal drive motor 452 is a drive motor that generates a driving force for moving the insertion and removal movable body 451 in the insertion and removal direction DX along the insertion and removal support part 4411 of the vertical movable body 441. The insertion and removal drive transmission unit 453 is a mechanism for transmitting a driving force of the insertion and removal drive motor 452 to the insertion and removal movable body 451.

In the insertion and removal movement mechanism 45, the insertion and removal movable body 451 moves in the insertion and removal direction DX along the insertion and removal support part 4411 of the vertical movable body 441 according to the driving force of the insertion and removal drive motor 452 transmitted from the insertion and removal drive transmission unit 453. When the insertion and removal movable body 451 moves, the feeder 25 gripped by the grip part 4512 moves in the insertion and removal direction DX on the insertion and removal guide part 4412 in accordance with the movement.

In the feeder insertion/removal device 4, the horizontal movement mechanism 43 and the vertical movement mechanism 44 operate before the insertion and removal movement mechanism 45 starts operating. Specifically, the horizontal movement strut body 431 moves on the horizontal support base 42 in the horizontal movement mechanism 43 and the vertical movable body 441 moves along the horizontal movement strut body 431 in the vertical movement mechanism 44 so that the insertion and removal guide part 4412 is located on the same straight line as the lower holding rail 242 of the holder 24. In this manner, in a state where the insertion and removal guide part 4412 is positioned on the same straight line as the lower holding rail 242 of the holder 24, the insertion and removal movement mechanism 45 moves the feeder 25 gripped by the grip part 4512 on the insertion and removal guide part 4412 according to the movement of the insertion and removal movable body 451, and moves the feeder 25 in the insertion and removal direction DX along the upper holding rail 241 and the lower holding rail 242 of the holder 24.

When the feeder 25 is moved in the insertion direction DX1, the insertion and removal movement mechanism 45 moves the feeder 25 on the insertion and removal guide part 4412. Thereafter, the insertion and removal movement mechanism 45 moves the feeder 25 along the upper holding rail 241 and the lower holding rail 242 until the upper positioning pin 256 and the lower positioning pin 257 are inserted into the upper pin insertion hole 243 and the lower pin insertion hole 244, respectively, and the feeder side connector 258 is connected to the unit side connector 245.

On the other hand, when the feeder 25 is moved in the extraction direction DX2, the insertion and removal movement mechanism 45 moves the feeder 25 along the upper holding rail 241 and the lower holding rail 242 so that the insertion of the upper positioning pin 256 and the lower positioning pin 257 into the upper pin insertion hole 243 and the lower pin insertion hole 244 is released and the connection of the feeder side connector 258 to the unit side connector 245 is released. Thereafter, the insertion and removal movement mechanism 45 moves the feeder 25 until the feeder is disposed on the insertion and removal guide part 4412.

The detection unit 454 configured to detect a load index value IV, which is an index of a load applied to the feeder 25 by the movement of the feeder 25 at the time of insertion and removal of the feeder 25 into and from the holder 24 by the insertion and removal movement mechanism 45. In the present embodiment, the detection unit 454 configured to detect a current value or a voltage value of the insertion and removal drive motor 452 as the load index value IV. The detection unit 454 may be configured to detect a load applied to the feeder 25 using a load cell or the like.

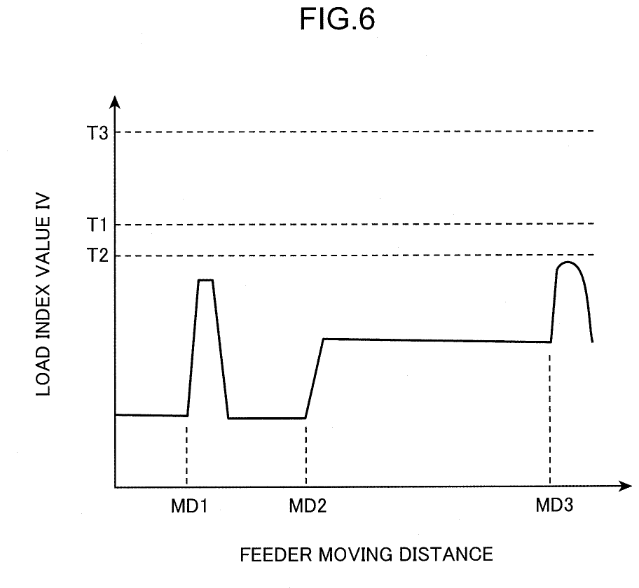

The load index value IV detected by the detection unit 454 increases as the load applied to the feeder 25 during insertion and removal into and from the holder 24 increases. The load index value IV changes according to the movement of the feeder 25 with respect to the holder 24. Description will be made of a change in the load index value IV when the feeder 25 is moved in the insertion direction DX1 by the insertion and removal movement mechanism 45 with reference to the graph of FIG. 6. In the following description, defined as a first distance MD1 is a distance from a movement start position of the feeder 25 on the insertion and removal guide part 4412 to a position where a distal end of the feeder 25 (an end where the upper positioning pin 256 and the lower positioning pin 257 are provided) reaches the feeder 25 that has been inserted into the holder 24. Similarly, defined as a second distance MD2 is a distance from the movement start position of the feeder 25 to a boundary position between the insertion and removal guide part 4412 and the lower holding rail 242. In addition, defined as a third distance MD3 is a distance from the movement start position of the feeder 25 to a position where the upper positioning pin 256 and the lower positioning pin 257 are respectively inserted into the upper pin insertion hole 243 and the lower pin insertion hole 244.

As illustrated in FIG. 6, when the feeder 25 moves by the first distance MD1 on the insertion and removal guide part 4412, the load index value IV starts to rise. This phenomenon is considered to occur because the distal end of the feeder 25 moving on the insertion and removal guide part 4412 comes into contact with the feeder 25 already inserted into the holder 24, thereby increasing the load applied to the moving feeder 25.

The load index value IV that starts to rise in response to the movement of the feeder 25 by the first distance MD1 decreases with further movement of the feeder 25 on the insertion and removal guide part 4412. Thereafter, when the feeder 25 moves by the second distance MD2 on the insertion and removal guide part 4412, the load index value IV again starts to rise. This phenomenon is considered to occur because a part that guides the movement of the feeder 25 is switched from the insertion and removal guide part 4412 to the upper holding rail 241 and the lower holding rail 242 of the holder 24, thereby increasing the load applied to the moving feeder 25.

The load index value IV that starts to rise in response to the movement of the feeder 25 by the second distance MD2 remains constant at a predetermined value as the feeder 25 moves along the upper holding rail 241 and the lower holding rail 242. Thereafter, when the feeder 25 moves by the third distance MD3 along the upper holding rail 241 and the lower holding rail 242, the load index value IV starts to rise again. This phenomenon is considered to occur because the load applied to the moving feeder 25 increases as the upper positioning pin 256 and the lower positioning pin 257 are inserted into the upper pin insertion hole 243 and the lower pin insertion hole 244, respectively.

During a period in which the feeder 25 is inserted into or removed from the holder 24, the detection unit 454 configured to detect the load index value IV that changes according to the movement of the feeder 25 with respect to the holder 24.

The control unit 49 is configured with a CPU, a ROM that stores a control program, a RAM for use as a work area of the CPU, and the like. The control unit 49 controls the display unit 46 and the communication unit 47 by execution, by the CPU, of the control program stored in the ROM, and controls each operation of the horizontal movement mechanism 43, the vertical movement mechanism 44, and the insertion and removal movement mechanism 45. The control unit 49 includes, as a functional configuration, a horizontal movement control unit 491, a vertical movement control unit 492, an insertion and removal control unit 493, a display control unit 494, a threshold setting unit 495, and a communication control unit 496.

The display control unit 494 configured to control display operation of various types of information by the display unit 46. The communication control unit 496 configured to control data communication with the management device 3 by the communication unit 47.

The horizontal movement control unit 491 configured to control the horizontal movement mechanism 43. Specifically, the horizontal movement control unit 491 configured to input a drive signal to the horizontal drive motor 432 to control the movement of the horizontal movement strut body 431 on the horizontal support base 42. The vertical movement control unit 492 configured to control the vertical movement mechanism 44. Specifically, the vertical movement control unit 492 configured to input the drive signal to the vertical drive motor 442 to control the movement of the vertical movable body 441 along the horizontal movement strut body 431. The insertion and removal control unit 493 configured to control the movement of the feeder 25 at the time of insertion and removal into and from the holder 24 by inputting a drive signal DS to the insertion and removal movement mechanism 45. Specifically, the insertion and removal control unit 493 configured to change the drive signal DS input to the insertion and removal drive motor 452 to control the movement of the feeder 25 at the time of insertion and removal into and from the holder 24 according to the movement of the insertion and removal movable body 451 along the insertion and removal support part 4411. In other words, the insertion and removal control unit 493 configured to control the movement of the feeder 25 at the time of insertion and removal into and from the holder 24 by changing an input value of the drive signal DS to the insertion and removal drive motor 452.

The threshold setting unit 495 configured to set the allowable threshold T1, the sign threshold T2, and the stop threshold T3 as various thresholds for use when the insertion and removal control unit 493 configured to control the insertion and removal drive motor 452. The various thresholds set by the threshold setting unit 495 are stored in the threshold storage unit 481.

The allowable threshold T1 is a threshold indicating an upper limit value of a variation allowable range of the load index value IV corresponding to the upper limit of the allowable range of the load applied to the feeder 25 at the time of insertion and removal into and from the holder 24. The sign threshold T2 is a threshold having a value smaller than the allowable threshold T1 with respect to the load index value IV, and is a threshold indicating that there is a sign that the load applied to the feeder 25 at the time of insertion into and removal into from the holder 24 exceeds the allowable range. The stop threshold T3 is a threshold larger than the allowable threshold T1 with respect to the load index value IV, and is a threshold indicating an upper limit value of a variation allowable range based on a rated current value or a rated voltage value of the insertion and removal drive motor 452.

The threshold setting unit 495 configured to set the allowable threshold T1 in accordance with a moving speed of the feeder 25 at the time of insertion into and removal from the holder 24. Specifically, the threshold setting unit 495 configured to set the allowable threshold T1 based on related data in which a rotation speed of the insertion and removal drive motor 452 correlated with the moving speed of the feeder 25 is associated with a current value or a voltage value of the insertion and removal drive motor 452 as the load index value IV. The threshold setting unit 495 configured to set the allowable threshold T1 to a smaller value as the moving speed of the feeder 25 decreases.

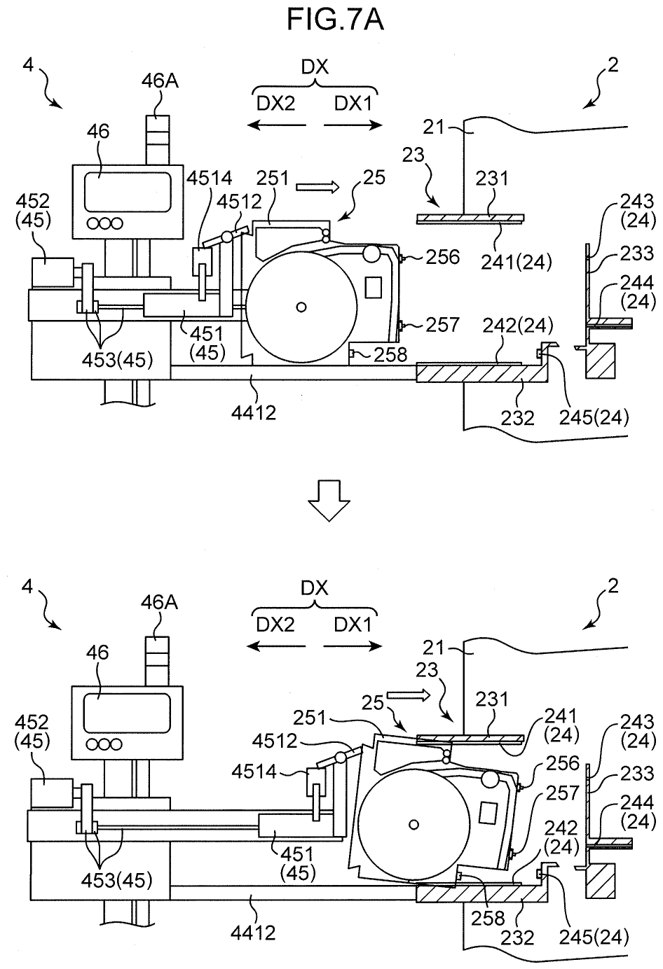

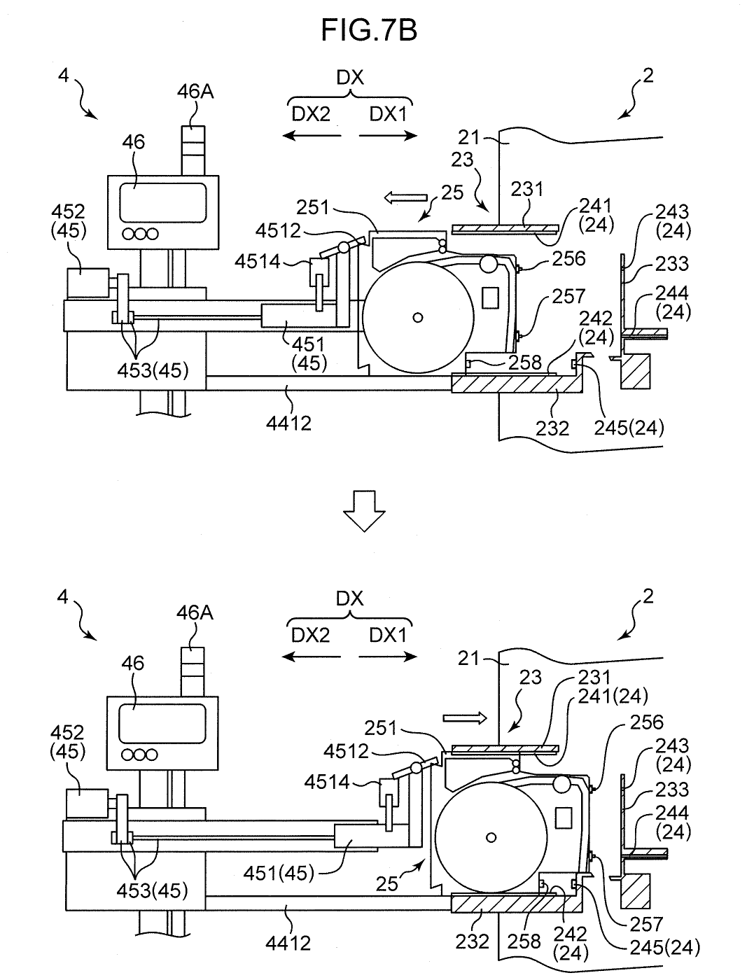

At the time of insertion and removal of the feeder 25 into and from the holder 24, there may occur a catch or the like that hinders insertion and removal of the feeder 25 (see FIG. 7A). For example, in a case where the feeder 25 takes an abnormal attitude of inclining, or in a case where a failure such as scratches, abrasion, or attached foreign matter occurs in the feeder 25 and the holder 24, there is a possibility that the feeder is caught at the time of insertion and removal of the feeder 25. In this case, it may be difficult to accurately insert and remove the feeder 25 into and from the holder 24. This may make it difficult to accurately supply a component from the feeder 25, resulting in having a possibility of reduction in productivity of the component mounting board in the component mounter 2.

Therefore, in the present embodiment, the insertion and removal control unit 493 configured to control the movement of the feeder 25 at the time of insertion and removal into and from the holder 24 by changing an input value of the drive signal DS to the insertion and removal drive motor 452 based on the load index value IV detected by the detection unit 454. This enables control of the movement of the feeder 25 at the time of insertion and removal by driving of the insertion and removal drive motor 452 according to a load applied to the feeder 25. For example, when the load applied to the feeder 25 increases due to occurrence of a catch or the like that hinders insertion and removal of the feeder 25, it is possible to control the movement of the feeder 25 at the time of insertion and removal according to the increase in the load. Therefore, the feeder 25 can be accurately inserted into and removed from the holder 24. As a result, a component can be accurately supplied from the feeder 25, so that a possibility can be reduced that the productivity of the component mounting board in the component mounter 2 is decreased.

The insertion and removal control unit 493 configured to execute standard control when the load index value IV detected by the detection unit 454 is less than the allowable threshold T1 set by the threshold setting unit 495. In the standard control, the insertion and removal control unit 493 configured to input the drive signal DS to the insertion and removal drive motor 452 so that the feeder 25 performs standard operation of moving along the insertion and removal direction DX, and controls the movement of the feeder 25 at the time of insertion and removal into and from the holder 24.

On the other hand, when the load index value IV detected by the detection unit 454 is equal to or larger than the allowable threshold T1, the insertion and removal control unit 493 executes retry control. In the retry control, the insertion and removal control unit 493 configured to input the drive signal DS to the insertion and removal drive motor 452 so that the feeder 25 performs retry operation of moving again after stopping movement along the insertion and removal direction DX, and controls the movement of the feeder 25 at the time of insertion and removal into and from the holder 24. In other words, in a case where the load index value IV becomes equal to or larger than the allowable threshold T1 and the load applied to the feeder 25 reaches the upper limit of the allowable range, the feeder 25 performs the retry operation by the execution of the retry control by the insertion and removal control unit 493. In the retry operation, the movement of the feeder 25 is temporarily stopped in response to the load index value IV becoming equal to or larger than the allowable threshold T1, and then the movement of the feeder 25 is resumed. Such retry operation of the feeder 25 enables an increase in the possibility of reducing the load applied to the feeder 25. Therefore, the feeder 25 can be more accurately inserted and removed into and from the holder 24.

The insertion and removal control unit 493 configured to execute the standard control such that the feeder 25 moves at a predetermined standard speed in the standard operation, and executes the retry control such that the feeder 25 moves at a retry speed lower than the standard speed in the retry operation. When the feeder 25 executes the retry operation by the execution of the retry control by the insertion and removal control unit 493, the feeder 25 moves at the retry speed lower than the standard speed. The retry operation of the feeder 25 of moving at a relatively slow speed enables a further increase in the possibility that the load applied to the feeder 25 is reduced. Therefore, the feeder 25 can be more accurately inserted and removed into and from the holder 24.

In addition, as illustrated in FIG. 7B, the insertion and removal control unit 493 configured to execute the retry control so that the feeder 25 stops moving in one direction side of one of the insertion direction DX1 and the extraction direction DX2 in the insertion and removal direction DX in the retry operation, then moves in the other direction side opposite to the one direction side by a predetermined opposite direction traveling distance, and then moves again in the one direction side. FIG. 7B shows an example in which the feeder 25 stops moving in the insertion direction DX1 in the retry operation, then moves in the extraction direction DX2 by the predetermined opposite direction traveling distance, and then moves again in the insertion direction DX1. Such retry operation of the feeder 25 can further increase the possibility of reducing the load applied to the feeder 25. Therefore, the feeder 25 can be more accurately inserted and removed into and from the holder 24.

It is assumed that the load index value IV detected by the detection unit 454 becomes equal to or larger than the allowable threshold T1 when the feeder 25 moves again in the one direction side in the retry operation. In this case, the insertion and removal control unit 493 configured to input the drive signal DS to the insertion and removal drive motor 452 so that the feeder 25 repeats the retry operation. Then, when the feeder 25 repeats the retry operation, the insertion and removal control unit 493 configured to input the drive signal DS to the insertion and removal drive motor 452 such that the opposite direction traveling distance in each retry operation becomes longer as the retry operation is repeated. As a result, as the retry operation of the feeder 25 is repeated, the possibility of reducing the load applied to the feeder 25 can be increased. This enables the feeder 25 to be accurately inserted into and removed from the holder 24 in accordance with the repetition of the retry operation of the feeder 25.

Next, it is assumed that the retry operation at the time of insertion of the feeder 25 into the holder 24 is repeated. Specifically, it is assumed that the load index value IV detected by the detection unit 454 maintains the allowable threshold T1 or more when a frequency of repetitions of the retry operation at the time of insertion of the feeder 25 reaches the preset frequency threshold T4. In this case, the insertion and removal control unit 493 configured to execute insertion cancel control of inputting the drive signal DS to the insertion and removal drive motor 452 so as to cancel the insertion of the feeder 25 into the holder 24 as a retry operation target. By the execution of the insertion cancel control by the insertion and removal control unit 493, insertion of the feeder 25 into the holder 24 as a retry operation target is cancelled. As a result, it is possible to restrict the feeder 25 from being inserted into the holder 24 in a state where an excessive load is applied to the feeder 25.

In the insertion cancel control, the insertion and removal control unit 493 configured to output the insertion cancel information DI1 indicating that the insertion of the feeder 25 into the holder 24 as a retry operation target is cancelled. The insertion cancel information DI1 output from the insertion and removal control unit 493 is used by the display control unit 494. The display control unit 494 configured to control the display unit 46 to display the insertion cancel information DI1. By checking the insertion cancel information DI1 displayed on the display unit 46, the operator can grasp that insertion of the feeder 25 into the holder 24 has been cancelled.

After the execution of the insertion cancel control, the insertion and removal control unit 493 configured to execute substitution insertion control. In this substitution insertion control, the insertion and removal control unit 493 configured to determine whether among the plurality of holders 24 in the component supply unit 23 of the component mounter 2, a substitute holder is present or not into which the feeder 25 can be inserted, as a substitution for the holder 24 into which insertion of the feeder 25 is to be cancelled. Specifically, the insertion and removal control unit 493 configured to determine whether among the plurality of holders 24, a substitute holder is present or not which is a holder 24 other than the holder 24 indicated by the arrangement data D1 stored in the arrangement storage unit 482 and into which the feeder 25 has not been inserted. When the substitute holder is present, the insertion and removal control unit 493 configured to input the drive signal DS to the insertion and removal drive motor 452 so that the feeder 25 moves in the insertion direction DX1 with respect to the substitute holder. When there are a plurality of substitute holders, the insertion and removal control unit 493 configured to input the drive signal DS to the insertion and removal drive motor 452 so that the feeder moves, in the insertion direction DX1, to a substitute holder at a position closest to the holder 24 into which the insertion of the feeder 25 is cancelled. As a result, when the feeder 25 is inserted into the substitute holder, components can be supplied from the feeder 25.

In a case where there is no substitute holder in the substitution insertion control, the insertion and removal control unit 493 configured to output the substitution impossible information DI2 indicating to that effect. The substitution impossible information DI2 output from the insertion and removal control unit 493 is used by the display control unit 494. The display control unit 494 configured to control the display unit 46 to display the substitution impossible information DI2. By checking the substitution impossible information DI2 displayed on the display unit 46, the operator can grasp a condition where no substitute holder is present into which the feeder 25 whose insertion into the holder 24 has been cancelled can be inserted.

The load applied to the feeder 25 at the time of insertion into or removal from the holder 24 may change in accordance with the moving speed of the feeder 25. Therefore, the load index value IV, which is an index of the load applied to the feeder 25, may also change in accordance with the moving speed of the feeder 25. Therefore, as described above, in accordance with the moving speed of the feeder 25 at the time of insertion and removal, the threshold setting unit 495 configured to set the allowable threshold T1 used when the insertion and removal control unit 493 configured to control the insertion and removal drive motor 452. Specifically, the threshold setting unit 495 configured to set the allowable threshold T1 to a smaller value as the moving speed of the feeder 25 decreases. As a result, the insertion and removal control unit 493 can more appropriately control the movement of the feeder 25 at the time of insertion and removal by the driving of the insertion and removal drive motor 452 based on comparison between the allowable threshold T1 set in accordance with the moving speed of the feeder 25 and the load index value IV. Therefore, the feeder 25 can be accurately inserted into and removed from the holder 24.

Next, it is assumed that the load index value IV detected by the detection unit 454 is less than the allowable threshold T1 and equal to or larger than the sign threshold T2 set by the threshold setting unit 495. In this case, the insertion and removal control unit 493 configured to output the sign information DI3 indicating that there is a sign that the load applied to the feeder 25 exceeds the allowable range at the time of insertion and removal into and from the holder 24 according to the movement of the feeder 25 by the driving of the insertion and removal drive motor 452. The sign information DI3 output from the insertion and removal control unit 493 is used by the display control unit 494. The display control unit 494 configured to control the display unit 46 to display the sign information DI3. By checking the sign information DI3 displayed on the display unit 46, the operator can grasp a condition where there is a sign that the load applied to the feeder 25 exceeds the allowable range.

The insertion and removal control unit 493 may be configured to cause the storage unit 48 to record history information when outputting the sign information DI3. The history information is information corresponding to output of the sign information DI3, and includes feeder specifying information for specifying the feeder 25 to be moved by the insertion and removal movement mechanism 45, holder specifying information for specifying the holder 24 into and from which the feeder 25 is to be inserted and removed, insertion and removal operation information indicating an operation condition of the insertion and removal movement mechanism 45, and the like. The operator can examine a factor of the output of the sign information DI3 by using the history information. For example, the operator can examine whether the feeder 25 has taken an abnormal attitude of inclining at the time of insertion and removal, or whether a failure such as scratches, abrasion, or attached foreign matter occurs in the feeder 25 and the holder 24.

Next, it is assumed that the load index value IV detected by the detection unit 454 is equal to or larger than the stop threshold T3 set by the threshold setting unit 495. In this case, the insertion and removal control unit 493 causes the insertion and removal drive motor 452 to stop driving. When the load index value IV becomes equal to or larger than the stop threshold T3, the insertion and removal drive motor 452 drives exceeding the upper limit value of the variation allowable range based on the rated current value or the rated voltage value of the insertion and removal drive motor 452. By stopping the driving of the insertion and removal drive motor 452 in such a case, it is possible to reduce a possibility of failure of the insertion and removal drive motor 452.

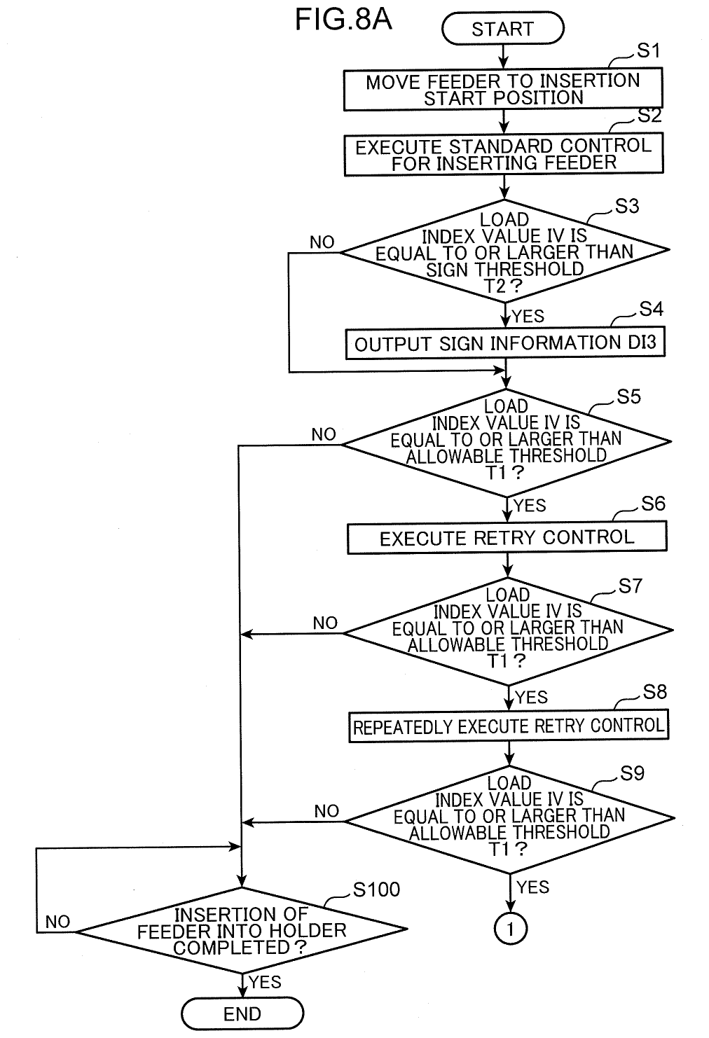

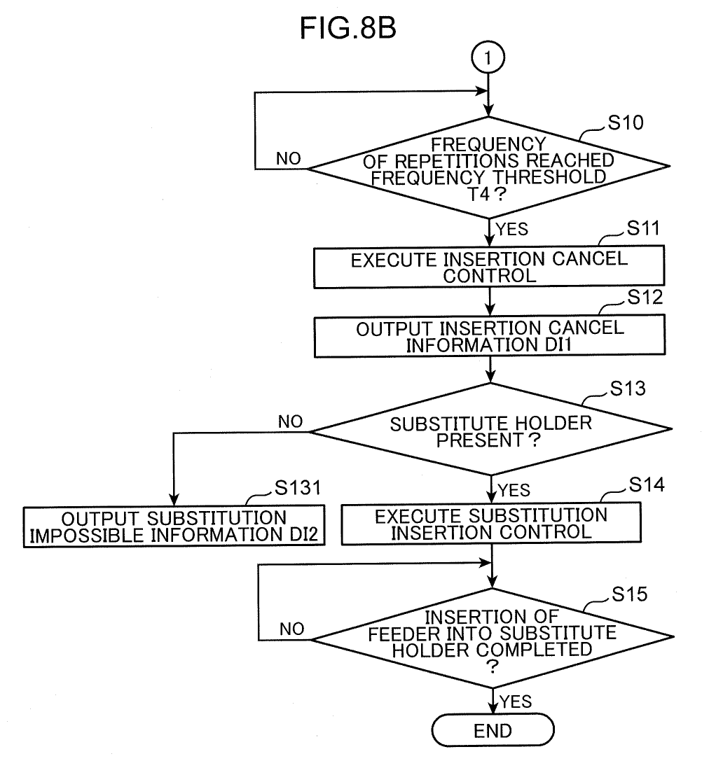

Next, operation of the feeder insertion/removal device 4 will be described in detail with reference to the flowcharts of FIGS. 8A and 8B. Here, the operation of the feeder insertion/removal device 4 when the feeder 25 is inserted into the holder 24 will be described.

When the communication unit 47 receives the arrangement data D1 transmitted from the management device 3, the operation of the feeder insertion/removal device 4 is started. The feeder insertion/removal device 4 moves to each position of the plurality of holders 24 in the component supply unit 23 by detecting, by the position detection sensor 412, the marking part 211 provided in the mounter main body 21. Then, the horizontal movement control unit 491 controls the horizontal movement mechanism 43 and the vertical movement control unit 492 controls the vertical movement mechanism 44 so that the insertion and removal guide part 4412 is positioned on the same straight line as the lower holding rail 242 of the holder 24. As a result, the feeder 25 gripped by the grip part 4512 of the insertion and removal movement mechanism 45 is moved to an insertion start position for starting insertion into the holder 24 (Step S1).

When the feeder 25 is disposed at the insertion start position, the insertion and removal control unit 493 executes the standard control based on the load index value IV detected by the detection unit 454 (Step S2). In the standard control, the insertion and removal control unit 493 inputs the drive signal DS to the insertion and removal drive motor 452 so that the feeder 25 performs the standard operation of moving along the insertion direction DX1. In such standard control, the insertion and removal control unit 493 determines whether the load index value IV is equal to or larger than the sign threshold T2 (Step S3). When the load index value IV is equal to or larger than the sign threshold T2 (YES in Step S3), the insertion and removal control unit 493 outputs the sign information DI3 (Step S4). The sign information DI3 output from the insertion and removal control unit 493 is displayed on the display unit 46.

In the standard control, the insertion and removal control unit 493 determines whether the load index value IV is equal to or larger than the allowable threshold T1 (Step S5). When the load index value IV is less than the allowable threshold T1 (NO in Step S5), the insertion and removal control unit 493 continues the standard control and determines whether or not the insertion of the feeder 25 into the holder 24 has been completed (Step S100). When the insertion of the feeder 25 is completed, the operation of the feeder insertion/removal device 4 ends.

When the load index value IV is equal to or larger than the allowable threshold T1 (YES in Step S5), the insertion and removal control unit 493 executes the retry control (Step S6). In the retry control, the insertion and removal control unit 493 controls the driving of the insertion and removal drive motor 452 so that the feeder 25 executes the retry operation. When the feeder 25 moves again in the insertion direction DX1 in the retry operation, the insertion and removal control unit 493 determines whether or not the load index value IV becomes equal to or larger than the allowable threshold T1 (Step S7). When the load index value IV is less than the allowable threshold T1 (NO in Step S7), the insertion and removal control unit 493 shifts the processing to Step S100 to determine whether or not the insertion of the feeder 25 into the holder 24 has been completed by the retry operation. When the insertion of the feeder 25 is completed, the operation of the feeder insertion/removal device 4 ends.

When the load index value IV is equal to or larger than the allowable threshold T1 (YES in Step S7), the insertion and removal control unit 493 repeatedly executes the retry control (Step S8). The insertion and removal control unit 493 determines whether or not the load index value IV becomes equal to or larger than the allowable threshold T1 while the feeder 25 moves again in the insertion direction DX1 in each retry operation repeated (Step S9). When the load index value IV is less than the allowable threshold T1 (NO in Step S9), the insertion and removal control unit 493 shifts the processing to Step S100 and determines whether or not the insertion of the feeder 25 into the holder 24 has been completed by the repetition of the retry operation. When the insertion of the feeder 25 is completed, the operation of the feeder insertion/removal device 4 ends.

When the load index value IV is equal to or larger than the allowable threshold T1 (YES in Step S9), the insertion and removal control unit 493 determines whether the frequency of repetitions of the retry operation at the time of insertion of the feeder 25 has reached the frequency threshold T4 or not (Step S10). When the frequency of repetitions of the retry operation has reached the frequency threshold T4 (YES in Step S10), the insertion and removal control unit 493 executes the insertion cancel control (Step S11). In the insertion cancel control, the insertion and removal control unit 493 inputs the drive signal DS to the insertion and removal drive motor 452 so as to cancel the insertion of the feeder 25 into the holder 24 as a retry operation target. At this time, the insertion and removal control unit 493 outputs the insertion cancel information DI1 (Step S12). The insertion cancel information DI1 output from the insertion and removal control unit 493 is displayed on the display unit 46.

After the execution of the insertion cancel control, the insertion and removal control unit 493 determines whether or not a substitute holder is present into which the feeder 25 whose insertion into the holder 24 is to be cancelled can be inserted (Step S13). In a case where there is no substitute holder (NO in Step S13), the insertion and removal control unit 493 outputs the substitution impossible information DI2 indicating to that effect (Step S131).

When the substitute holder is present (YES in Step S13), the insertion and removal control unit 493 executes the substitution insertion control (Step S14). In the substitution insertion control, the insertion and removal control unit 493 inputs the drive signal DS to the insertion and removal drive motor 452 so that the feeder 25 moves in the insertion direction DX1 with respect to the substitute holder. Then, the insertion and removal control unit 493 determines whether or not the insertion of the feeder 25 into the substitute holder has been completed (Step S15). When the insertion of the feeder 25 into the substitute holder is completed, the operation of the feeder insertion/removal device 4 ends.

As described above, in the feeder insertion/removal device 4 according to the present embodiment, the insertion and removal control unit 493 controls the movement of the feeder 25 at the time of insertion and removal into and from the holder 24 by changing an input value of the drive signal DS to the insertion and removal drive motor 452 based on the load index value IV detected by the detection unit 454. This enables control of the movement of the feeder 25 at the time of insertion and removal by driving of the insertion and removal drive motor 452 according to a load applied to the feeder 25. Therefore, the feeder 25 can be accurately inserted into and removed from the holder 24.

The component mounting system 1 includes the feeder insertion/removal device 4 capable of accurately inserting and removing the feeder 25 into and from the plurality of holders 24 in the component mounter 2. This enables accurate supply of a component from the feeder 25 inserted into the holder 24, thereby reducing a possibility of reduction in productivity of the component mounting board in the component mounter 2.

Note that the above-described specific embodiment mainly includes the disclosure having the following configurations.

A feeder insertion/removal device according to one aspect of the present disclosure is a device for inserting and removing a feeder that supplies a component into and from each of a plurality of holders capable of holding the feeder in a component mounter that mounts the component on a board. The feeder insertion/removal device includes: an insertion and removal movement mechanism configured to move the feeder along an insertion and removal direction with respect to the holder; a detection unit configured to detect a load index value that is an index of a load applied to the feeder by movement of the feeder at the time of insertion and removal of the feeder into and from the holder by the insertion and removal movement mechanism; and an insertion and removal control unit configured to control the movement of the feeder at the time of insertion and removal into and from the holder by inputting a drive signal to the insertion and removal movement mechanism based on the load index value detected by the detection unit.

According to the feeder insertion/removal device, the insertion and removal movement mechanism controlled by the insertion and removal control unit moves the feeder in the insertion and removal direction to insert and remove the feeder into and from each of the plurality of holders in the component mounter. At this time, the insertion and removal control unit inputs the drive signal to the insertion and removal movement mechanism based on the load index value serving as an index of a load applied to the feeder at the time of insertion and removal to and from the holder. This enables control of the movement of the feeder at the time of insertion and removal, the movement being caused by the insertion and removal movement mechanism, according to a load applied to the feeder. For example, when the load applied to the feeder increases due to occurrence of a catch or the like that hinders insertion and removal of the feeder, it is possible to control the movement of the feeder at the time of insertion and removal according to the increase in the load. Therefore, the feeder can be accurately inserted into and removed from the holder. As a result, a component can be accurately supplied from the feeder, so that a possibility can be reduced that the productivity of the component mounting board in the component mounter is decreased.

In the above feeder insertion/removal device, the insertion and removal movement mechanism may include a drive motor that generates a driving force for moving the feeder along the insertion and removal direction, the detection unit may detect a current value or a voltage value of the drive motor as the load index value, and the insertion and removal control unit may change a drive signal input to the drive motor to control the movement of the feeder at the time of insertion and removal into and from the holder.

In this aspect, the detection unit configured to detect the current value or the voltage value of the drive motor as the load index value used when the insertion and removal control unit configured to change an input value of the drive signal to the drive motor. Accordingly, the detection unit can detect the load index value without using a load detection sensor such as a load cell.

In the above feeder insertion/removal device, when the load index value detected by the detection unit is less than an allowable threshold set in advance, the insertion and removal control unit may execute standard control of inputting the drive signal to the insertion and removal movement mechanism so that the feeder performs standard operation of moving along the insertion and removal direction, and controlling the movement of the feeder at the time of insertion and removal, and when the load index value detected by the detection unit becomes equal to or larger than the allowable threshold, the insertion and removal control unit may execute retry control of inputting the drive signal to the insertion and removal movement mechanism so that the feeder performs retry operation of moving again after stopping the movement along the insertion and removal direction, and controlling the movement of the feeder at the time of insertion and removal.

In this aspect, the insertion and removal control unit configured to execute the standard control so that the feeder performs the standard operation when the load index value is less than the allowable threshold, and executes the retry control so that the feeder performs the retry operation when the load index value is equal to or larger than the allowable threshold. In other words, when the load index value becomes equal to or larger than the allowable threshold and the load applied to the feeder reaches an upper limit of an allowable range, the feeder performs the retry operation by the execution of the retry control by the insertion and removal control unit. In the retry operation, the movement of the feeder is temporarily stopped in response to the load index value becoming equal to or larger than the allowable threshold, and then the movement of the feeder is resumed. Such retry operation of the feeder can increase a possibility of reducing the load applied to the feeder. Therefore, the feeder can be more accurately inserted and removed into and from the holder.

In the above feeder insertion/removal device, the insertion and removal control unit may execute the retry control so that after stopping movement in one direction side of one of an insertion direction and an extraction direction in the insertion and removal direction in the retry operation, the feeder moves in another direction side opposite to the one direction side by a predetermined opposite direction traveling distance, and then moves in the one direction side again.

In this aspect, when the feeder performs the retry operation by the execution of the retry control by the insertion and removal control unit, after the movement of the feeder in one direction side is temporarily stopped, the feeder moves in the other direction opposite to the one direction, and then the movement of the feeder in the one direction side is resumed. Such retry operation of the feeder can further increase the possibility of reducing the load applied to the feeder. Therefore, the feeder can be more accurately inserted and removed into and from the holder.

In the above feeder insertion/removal device, the insertion and removal control unit may execute the standard control so that the feeder moves at a predetermined standard speed in the standard operation, and execute the retry control so that the feeder moves at a retry speed lower than the standard speed in the retry operation.

In this aspect, when the feeder performs the retry operation by the execution of the retry control by the insertion and removal control unit, the feeder moves at the retry speed lower than the standard speed. It is possible to further increase the possibility that the load applied to the feeder is reduced by the retry operation of the feeder of moving at a relatively slow speed. Therefore, the feeder can be more accurately inserted and removed into and from the holder.

In the above feeder insertion/removal device, the insertion and removal control unit may input the drive signal to the insertion and removal movement mechanism so that the feeder repeats the retry operation when the load index value detected by the detection unit becomes equal to or larger than the allowable threshold while the feeder is moving in the one direction side again in the retry operation, and when the feeder repeats the retry operation, may input the drive signal to the insertion and removal movement mechanism so that the opposite direction traveling distance in each retry operation becomes longer as the retry operation is repeated.

In this aspect, when the feeder repeats the retry operation by the execution of the retry control by the insertion and removal control unit, the opposite direction traveling distance of the feeder is set to be longer as the retry operation is repeated. As a result, as the retry operation of the feeder is repeated, the possibility of reducing the load applied to the feeder can be increased. Therefore, the feeder can be accurately inserted into and removed from the holder in accordance with the repetition of the retry operation of the feeder.

In the above feeder insertion/removal device, the insertion and removal control unit may execute insertion cancel control of inputting the drive signal to the insertion and removal movement mechanism so as to cancel insertion of the feeder into a holder as a target of the retry operation in a case where the load index value detected by the detection unit maintains the allowable threshold or more when a frequency of repetitions of the retry operation of setting the insertion direction to the one direction as the retry operation of the feeder reaches a preset frequency threshold.

In this aspect, in a case where the load index value maintains the allowable threshold or more when the frequency of repetitions of the retry operation at the time of insertion of the feeder into the holder reaches the predetermined frequency threshold, the insertion and removal control unit configured to execute the insertion cancel control. By the execution of the insertion cancel control by the insertion and removal control unit, insertion of the feeder into the holder that is a target of the retry operation is cancelled. This makes it possible to restrict the feeder from being inserted into the holder in a state where an excessive load is applied to the feeder.

In the above feeder insertion/removal device, the insertion and removal control unit may execute substitution insertion control of determining, after execution of the insertion cancel control, whether or not, among the plurality of holders, a substitute holder is present into which the feeder is capable of being inserted, as a substitute for a holder into which insertion of the feeder is to be cancelled, and when the substitute holder is present, inputting the drive signal to the insertion and removal movement mechanism so that the feeder moves in the insertion direction with respect to the substitute holder.

In this aspect, in a case where a substitute holder is present into which the feeder whose insertion into the holder has been cancelled can be inserted, the insertion and removal control unit configured to execute the substitution insertion control for inserting the feeder into the substitute holder. As a result, when the feeder is inserted into the substitute holder, components can be supplied from the feeder.

In the above feeder insertion/removal device, in a case where the substitute holder is not present in the substitution insertion control, the insertion and removal control unit may output substitution impossible information indicating that the substitute holder is not present.

In this aspect, in a case where there is no substitute holder into which the feeder whose insertion into the holder has been cancelled can be inserted, the insertion and removal control unit configured to output the substitution impossible information. By using the substitution impossible information output from the insertion and removal control unit, it is possible, for example, to cause the operator to grasp a condition where no substitute holder is present.

In the above feeder insertion/removal device, in the insertion cancel control, the insertion and removal control unit may output insertion cancel information indicating cancellation of insertion of the feeder into a holder as a target for the retry operation.

In this aspect, the insertion and removal control unit configured to output the insertion cancel information in the insertion cancel control. By using the insertion cancel information output from the insertion and removal control unit, it is possible, for example, to cause the operator to grasp a condition of cancelling the insertion of the feeder into the holder.

In the above feeder insertion/removal device, when the load index value detected by the detection unit is less than the allowable threshold and is equal to or larger than a preset sign threshold, the insertion and removal control unit may output sign information indicating that there is a sign that a load applied to the feeder exceeds an allowable range at the time of insertion and removal to and from the holder in accordance with movement of the feeder by the insertion and removal movement mechanism.

In this aspect, the insertion and removal control unit configured to output the sign information when the load index value is less than the allowable threshold and equal to or larger than the sign threshold. By using the sign information output from the insertion and removal control unit, the operator is allowed to grasp a condition, for example, where there is a sign that the load applied to the feeder exceeds the allowable range.

The above feeder insertion/removal device may further include a display unit that displays information output from the insertion and removal control unit.

In this aspect, the display unit displays the information output from the insertion and removal control unit. By checking the information displayed on the display unit, the operator can grasp a condition of insertion and removal of the feeder into and from the holder by the feeder insertion/removal device.

The above feeder insertion/removal device may further include a threshold setting unit configured to set the allowable threshold according to a moving speed of the feeder at the time of insertion and removal to and from the holder.

The load applied to the feeder at the time of insertion into or removal from the holder may change in accordance with the moving speed of the feeder. Therefore, the load index value, which is an index of the load applied to the feeder, may also change in accordance with the moving speed of the feeder. Therefore, in accordance with the moving speed of the feeder at the time of insertion and removal, the threshold setting unit sets the allowable threshold used when the insertion and removal control unit controls the insertion and removal movement mechanism. As a result, the insertion and removal control unit can more appropriately control the movement of the feeder at the time of insertion and removal by the insertion and removal movement mechanism based on comparison between the allowable threshold set in accordance with the moving speed of the feeder and the load index value. Therefore, the feeder can be accurately inserted into and removed from the holder.

A component mounting system according to another aspect of the present disclosure includes: a component mounter that has a plurality of holders each capable of holding a feeder that supplies a component, and mounts a component supplied by the feeder on a board; and the above feeder insertion/removal device for inserting and removing the feeder into and from each of the plurality of holders.

The component mounting system includes the feeder insertion/removal device capable of accurately inserting and removing the feeder into and from the plurality of holders in the component mounter. This enables accurate supply of a component from the feeder inserted into the holder, so that a possibility can be reduced that the productivity of the component mounting board in the component mounter is decreased.

As described above, the present disclosure provides a feeder insertion/removal device capable of accurately inserting and removing a feeder into and from a plurality of holders in a component mounter, and a component mounting system including the feeder insertion/removal device.

1. A feeder insertion/removal device for inserting and removing a feeder that supplies a component into and from each of a plurality of holders capable of holding the feeder in a component mounter that mounts the component on a board, the feeder insertion/removal device comprising:
an insertion and removal movement mechanism configured to move the feeder along an insertion and removal direction with respect to the holder;
a detector configured to detect a load index value that is an index of a load applied to the feeder by movement of the feeder at a time of insertion and removal of the feeder into and from the holder by the insertion and removal movement mechanism; and
an insertion and removal controller configured to control the movement of the feeder at the time of insertion and removal into and from the holder by inputting a drive signal to the insertion and removal movement mechanism based on the load index value detected by the detector.

2. The feeder insertion/removal device according to claim 1, wherein
the insertion and removal movement mechanism includes a drive motor configured to generate a driving force for moving the feeder along the insertion and removal direction,
the detector is configured to detect a current value or a voltage value of the drive motor as the load index value, and
the insertion and removal controller is configured to change the drive signal input to the drive motor to control the movement of the feeder at the time of insertion and removal into and from the holder.

3. The feeder insertion/removal device according to claim 1, wherein
when the load index value detected by the detector is less than an allowable threshold set in advance, the insertion and removal controller is configured to execute standard control of inputting the drive signal to the insertion and removal movement mechanism so that the feeder performs standard operation of moving along the insertion and removal direction, and control the movement of the feeder at the time of insertion and removal, and
when the load index value detected by the detector becomes equal to or larger than the allowable threshold, the insertion and removal controller is configured to execute retry control of inputting the drive signal to the insertion and removal movement mechanism so that the feeder performs retry operation of moving again after stopping the movement along the insertion and removal direction, and is configured to control the movement of the feeder at the time of insertion and removal.

4. The feeder insertion/removal device according to claim 3, wherein
the insertion and removal controller is configured to execute the retry control so that after stopping movement in one direction side of one of an insertion direction and an extraction direction in the insertion and removal direction in the retry operation, the feeder moves in another direction side opposite to the one direction side by a predetermined opposite direction traveling distance, and then moves in the one direction side again.

5. The feeder insertion/removal device according to claim 3, wherein
the insertion and removal controller is configured to execute the standard control so that the feeder moves at a predetermined standard speed in the standard operation, and execute the retry control so that the feeder moves at a retry speed lower than the standard speed in the retry operation.

6. The feeder insertion/removal device according to claim 4, wherein
the insertion and removal controller is configured to
input the drive signal to the insertion and removal movement mechanism so that the feeder repeats the retry operation when the load index value detected by the detector becomes equal to or larger than the allowable threshold while the feeder is moving in the one direction side again in the retry operation, and
when the feeder repeats the retry operation, input the drive signal to the insertion and removal movement mechanism so that the opposite direction traveling distance in each retry operation becomes longer as the retry operation is repeated.

7. The feeder insertion/removal device according to claim 6, wherein
the insertion and removal controller is configured to execute insertion cancel control of inputting the drive signal to the insertion and removal movement mechanism so as to cancel insertion of the feeder into a holder as a target of the retry operation in a case where the load index value detected by the detector maintains the allowable threshold or more when a frequency of repetitions of the retry operation of setting the insertion direction to the one direction as the retry operation of the feeder reaches a preset frequency threshold.

8. The feeder insertion/removal device according to claim 7, wherein
the insertion and removal controller is configured to execute substitution insertion control of determining, after execution of the insertion cancel control, whether or not, among the plurality of holders, a substitute holder is present into which the feeder is capable of being inserted, as a substitute for a holder into which insertion of the feeder is to be cancelled, and when the substitute holder is present, input the drive signal to the insertion and removal movement mechanism so that the feeder moves in the insertion direction with respect to the substitute holder.

9. The feeder insertion/removal device according to claim 8, wherein
in a case where the substitute holder is not present in the substitution insertion control, the insertion and removal controller is configured to output substitution impossible information indicating that the substitute holder is not present.

10. The feeder insertion/removal device according to claim 7, wherein
in the insertion cancel control, the insertion and removal controller is configured to output insertion cancel information indicating cancellation of insertion of the feeder into a holder as a target for the retry operation.

11. The feeder insertion/removal device according to claim 3, wherein
when the load index value detected by the detector is less than the allowable threshold and is equal to or larger than a preset sign threshold, the insertion and removal controller is configured to output sign information indicating that there is a sign that a load applied to the feeder exceeds an allowable range at the time of insertion and removal to and from the holder in accordance with movement of the feeder by the insertion and removal movement mechanism.

12. The feeder insertion/removal device according to claim 9, further comprising:
a display configured to display information output from the insertion and removal controller.

13. The feeder insertion/removal device according to claim 3, further comprising:
a threshold controller configured to set the allowable threshold according to a moving speed of the feeder at the time of insertion and removal to and from the holder.

14. A component mounting system comprising:
a component mounter that has a plurality of holders each capable of holding a feeder that supplies a component, and is configured to mount a component supplied by the feeder on a board; and
the feeder insertion/removal device according to claim 1 for inserting and removing the feeder into and from each of the plurality of holders.

15. The feeder insertion/removal device according to claim 2, wherein
when the load index value detected by the detector is less than an allowable threshold set in advance, the insertion and removal controller is configured to execute standard control of inputting the drive signal to the insertion and removal movement mechanism so that the feeder performs standard operation of moving along the insertion and removal direction, and control the movement of the feeder at the time of insertion and removal, and
when the load index value detected by the detector becomes equal to or larger than the allowable threshold, the insertion and removal controller is configured to execute retry control of inputting the drive signal to the insertion and removal movement mechanism so that the feeder performs retry operation of moving again after stopping the movement along the insertion and removal direction, and is configured to control the movement of the feeder at the time of insertion and removal.

16. The feeder insertion/removal device according to claim 15, wherein
the insertion and removal controller is configured to execute the retry control so that after stopping movement in one direction side of one of an insertion direction and an extraction direction in the insertion and removal direction in the retry operation, the feeder moves in another direction side opposite to the one direction side by a predetermined opposite direction traveling distance, and then moves in the one direction side again.

17. The feeder insertion/removal device according to claim 4, wherein
the insertion and removal controller is configured to execute the standard control so that the feeder moves at a predetermined standard speed in the standard operation, and execute the retry control so that the feeder moves at a retry speed lower than the standard speed in the retry operation.

18. The feeder insertion/removal device according to claim 8, wherein
in the insertion cancel control, the insertion and removal controller is configured to output insertion cancel information indicating cancellation of insertion of the feeder into a holder as a target for the retry operation.

19. The feeder insertion/removal device according to claim 4, wherein
when the load index value detected by the detector is less than the allowable threshold and is equal to or larger than a preset sign threshold, the insertion and removal controller is configured to output sign information indicating that there is a sign that a load applied to the feeder exceeds an allowable range at the time of insertion and removal to and from the holder in accordance with movement of the feeder by the insertion and removal movement mechanism.

20. The feeder insertion/removal device according to claim 10, further comprising:
a display configured to display information output from the insertion and removal controller.
